(19) United States
(12) Patent Application Publication
(10) Pub. No.: US 2007/0030871 A1
(43) Pub. Date: Feb. 8, 2007

(54) SEMICONDUCTOR DEVICE HAVING LOW RESISTANCE CONTACT TO P-TYPE SEMICONDUCTOR LAYER OF A WIDE BAND GAP COMPOUND AND METHOD FOR MANUFACTURING THE SAME

(75) Inventor: Kyu-Pil LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/425,616

(22) Filed: Jun. 21, 2006

(30) Foreign Application Priority Data
Aug. 5, 2005 (KR) 10-2005-0071686

(51) Int. Cl. H01S 5/00

(52) U.S. Cl. 372/46.01

(57) ABSTRACT

A semiconductor device having low resistance contact to p-type semiconductor layer of a wide band gap compound and a method for manufacturing the same are provided. The semiconductor device includes a p-type semiconductor layer of a GaN based compound formed on a substrate, a p-type carbon nanotube layer, and a metal contact. The p-type carbon nanotube layer is joined to the p-type semiconductor layer of the GaN based compound, and the metal contact is joined to the p-type carbon nanotube layer.

### CROSS-REFERENCE TO RELATED APPLICATIONS

This application claims priority from Korean Patent Application No. 10-2005-0071686, which was filed on 5 Aug. 2005. The disclosure of Korean Patent Application No. 10-2005-0071686 is incorporated by reference in its entirety.

### BACKGROUND

1. Technical Field

This disclosure relates to compound semiconductor devices, and more particularly, to a compound semiconductor device having a low resistance contact to a p-type semiconductor layer of a wide band gap compound and a method of manufacturing the same.

2. Description of the Related Art

A semiconductor material possessing a wide band gap is understood to be a material that is very appropriate for devices or applications that require high speed or high temperature operation. For example, a semiconductor of a Ga—N based compound has a large energy band gap (E_{g}) of about 3.4 eV compared to the conventional III—V compound semiconductor.

Since a semiconductor of the Ga—N based compound has a very large energy band gap E_{g} compared to the conventional silicon-based semiconductor having an energy band gap of about 1.1 eV, the semiconductor of the Ga—N based compound is considered to be useful for high voltage power devices operating in the range of hundreds of volts to thousands of volts, or a device operating under high temperature environment. When a semiconductor device is realized using the semiconductor of the Ga—N based compound, it is required to realize a p-n junction, a p-n-p junction, and an n-p-n junction using the semiconductor of the Ga—N based compound. At this point, it is required to use a p-type semiconductor layer of the Ga—N based compound doped with p-conductive type semiconductors.

There have been attempts to apply a p-type semiconductor layer of a Ga—N based compound to a spaceship requiring a high temperature atmosphere or application of a high performance device, or to a device used for military equipment or a power plant. Also, attempts have been made to use the p-type semiconductor layer of a Ga—N based compound for an optical device material for securing blue light or white light.

However, it has been known that the p-type semiconductor layer of a Ga—N based compound possesses a relatively high sheet resistance and a relatively high contact resistance. To improve the electrical characteristics of the p-type semiconductor layer of a Ga—N based compound, attempts have been made to realize a contact that contacts the p-type semiconductor layer of a Ga—N based compound using a p-type ohmic contact.

For bipolar junction transistors (BJTs) and heterojunction bipolar transistors (HBTs), which are representative power devices among semiconductor devices estimated as being applicable to the semiconductor layer of the p-type Ga—N based compound, it is considered very important to reduce contact resistance with respect to the semiconductor layer of the p-type Ga—N based compound. For example, since reducing the resistance of a base in an n-p-n type HBT has a great influence on the characteristics of the HBT device, it is very important to achieve a p-type ohmic contact so as to improve the performance of the HBT.

For that purpose, attempts have been made to form a contact using an electrode having a plurality of metal layers stacked therein. However, since a contact between a metal layer and a semiconductor layer may be accompanied by a large potential barrier, it is very difficult to realize such a p-type ohmic contact. Therefore, development of a method for realizing the p-type ohmic contact to the semiconductor layer of the p-type Ga—N based compound is highly required.

Embodiments of the invention address these and other disadvantages of the related art.

### SUMMARY

Embodiments of the invention provide a semiconductor device of a wide band gap compound and a method of manufacturing the same, capable of reducing resistance between a p-type conductive layer and a contact contacting the p-type conductive layer when using a semiconductor layer of a wide band gap compound (e.g., a Ga—N based compound) for the p-type conductive layer.

### BRIEF DESCRIPTION OF THE DRAWINGS

The above and other features and advantages of the invention will become more apparent by describing in detail exemplary embodiments thereof with reference to the attached drawings.

FIGS. 1 through 4 are sectional diagrams illustrating the formation of a p-type ohmic contact to a p-type semiconductor layer of a wide band gap compound according to some embodiments of the invention.

FIG. 5 is a schematic diagram illustrating an exemplary test piece that may be used in measuring I (current) versus V (voltage) characteristics of a p-n junction formed in accordance with embodiments of the invention.

FIG. 6 is a graph illustrating the measured I versus V characteristics of the p-n junction formed in accordance with embodiments of the invention, which is helpful in explaining the resistance improvement effect of a p-type ohmic contact to a p-type semiconductor layer of a wide band gap compound that is achieved by embodiments of the invention.

FIG. 7 is a schematic sectional view illustrating a HBT semiconductor device having a p-type ohmic contact to a p-type semiconductor layer of a wide band gap compound according to an embodiment of the present invention.

### DETAILED DESCRIPTION

The invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure is thorough and complete, and fully conveys the inventive principles found in embodiments of the invention to those skilled in the art.

To use a semiconductor material of a wide band gap such as a Ga—N based semiconductor material for a p-type layer of a semiconductor device, some embodiments of the invention provide a technology introducing a p-type carbon nanotube layer into an interface between a metal contact and a p-type semiconductor layer of a Ga—N based compound. This reduces the relatively high sheet resistance and/or contact resistance in the p-type semiconductor layer of the p-type Ga—N based compound, which is presently considered to be a disadvantage.

In a semiconductor material of a wide band gap such as a Ga—N based material, for example, a semiconductor material of a Ga—N based compound (e.g., InₓGa_{y}N and AlₓGa_{y}N) in which GaN or Ga is partially replaced by other element, GaN has an energy band gap E_{g} of about 3.4 eV. GaN is expected to be useful in improving the performance of a device, which will be used as a high voltage power device. According to some embodiments of the invention, it is possible to reduce the contact resistance of a p-type GaN layer having a relatively large sheet resistance by introducing a p-type of carbon nanotube layer to an interface between a metal contact and the p-type GaN layer. Therefore, a high power device such as a HBT using a p-type GaN layer for a base may be provided, so that the performance improvement of the HBT may be achieved.

When forming a p-type layer by doping a semiconductor material of a Ga—N based compound with an acceptor, it is known that a Ga—N based p-type semiconductor layer represents considerably high sheet resistance and/or contact resistance. This high sheet resistance and/or contact resistance is considered to be an obstacle in applying a semiconductor material of a Ga—N based compound (e.g., a p-type GaN layer) to an electrical device (e.g.; a HBT, a HEMT, a MESFET, and a BJT) and/or an optical diode or a laser diode.

A dopant, such as magnesium ions, may be used to dope a GaN layer and form a p-type layer. Magnesium ions have a very large ionization energy of about 170 meV at room temperature. Therefore, only 10-15% of the dose amount implanted at room temperature serves as impurities (or substantial dopants). Accordingly, a p-type GaN layer has a relatively low sheet resistance. To improve the low sheet resistance, introduction of a contact realizing relatively low contact resistance is required.

The GaN layer is a material of wide band gap having an energy band gap Eg of about 3.4 eV and having an electron affinity of about 4.1 eV. In comparison, it is difficult for metal to achieve a sufficiently large work function (most metals have a work function of 5 eV or less), so a considerably large potential barrier is formed between the GaN layer and the metal contact. Therefore, when a metal contact is allowed to directly contact a p-type GaN layer, it is very difficult to realize a p-type ohmic contact.

Also, since nitrogen atoms may exit from the GaN layer, and the interface between the GaN layer and the metal contact may be changed into an n-type conductive layer while the metal contact is allowed to directly contact the p-type GaN layer, it is also difficult to form a p-type ohmic contact in a p-type GaN layer.

Chemically speaking, one carbon atom may be bonded to three adjacent carbon atoms to form a hexagonal ring shape. A planar layer containing many of these hexagonal carbon rings looks similar to a honeycomb and may be rolled into a cylindrical shape to form carbon nanotubes. The carbon nanotubes may have a diameter of about several nanometers (nm) to tens of nm, and the length may be several tens to several thousands of times longer than the diameter. Such carbon nanotubes may possess both conductor or semiconductor characteristics depending on the particular application. Also, the carbon nanotubes may have electrical characteristics of p-type conductivity through a chemical process.

A single wall carbon nanotube may have both intrinsic metal and semiconductor characteristics. A bulk of carbon nanotubes may be understood to be a mixture where ⅓ of the bulk represents metal characteristics and ⅔ of the bulk represent semiconductor characteristics.

Therefore, according to embodiments of the invention, when a p-type carbon nanotube layer is introduced on a p-type GaN layer and a metal contact is introduced on the p-type carbon nanotube layer, a contact similar to a contact between p-type semiconductor layers may be realized between the p-type GaN layer and the p-type carbon nanotube, and simultaneously, a contact similar to a contact between metal layers may be realized between the metal contact and the carbon nanotube. That is, bonding between the metal contact and the carbon nanotubes having metal characteristics may occur, and bonding between the p-type GaN layer and the carbon nanotubes having semiconductor characteristics may occur.

That is, as the layer of p-type carbon nanotubes is introduced between the p-type GaN layer and the metal contact, a potential barrier between the p-type GaN layer and the metal contact is substantially lowered, so that a p-type ohmic contact is formed. Therefore, the contact resistance is lowered and a larger current may flow through the p-type GaN layer, so that a current flowing through the p-type GaN layer increases and the sheet resistance may be reduced.

FIGS. I through 4 are sectional diagrams illustrating the formation of a p-type ohmic contact to a p-type semiconductor layer of a wide band gap compound according to some embodiments of the invention.

Referring to FIG. 1, a p-type GaN layer 110 is formed on a substrate 100. The GaN layer 110 may be grown on the substrate 100 using metal organic chemical vapor deposition (MOCVD). The substrate 100 may be a sapphire substrate. It is possible to allow the GaN layer 110 to have p-type conductivity by performing ion-implantation on the GaN layer 110 using acceptors for dopants, or by performing an in-situ doping process. The dopants may include magnesium.

In the illustrated embodiments, although the description is made using an exemplary GaN layer 110, it is possible to form a layer 120 using a semiconductor material of a Ga—N based compound (e.g., InₓGa_{y}N and AlₓGa_{y}N), in which Ga is partially replaced by another element.

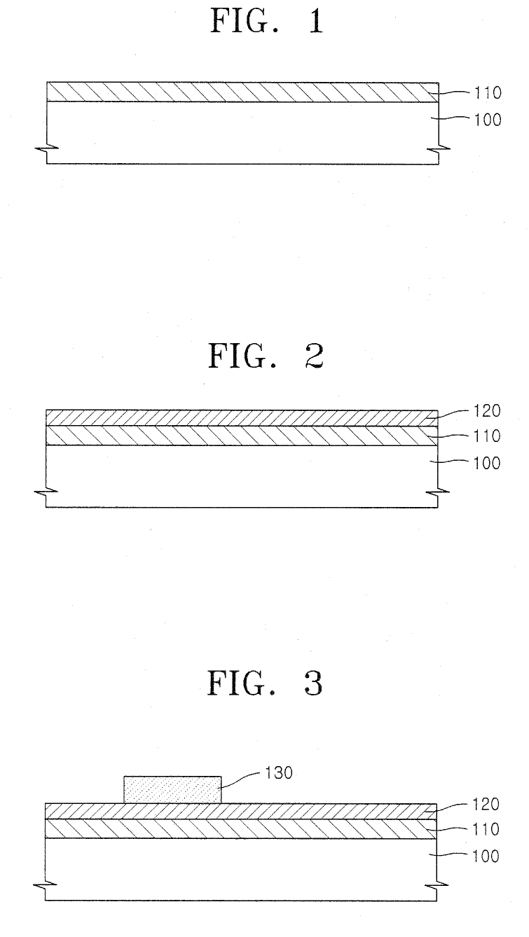

Referring to FIG. 2, a carbon nanotube layer 120 is formed on the p-type GaN layer 110. The carbon nanotube layer 120 may be understood as a layer consisting of many carbon nanotubes. Currently, it is known that the carbon nanotubes may be synthesized using a variety of methods.

For example, carbon nanotubes may be formed using an arc discharge accompanied by a catalyst to form a powder. The carbon nanotubes may also be formed using a laser deposition method, a method of using a plasma chemical vapor deposition apparatus, or a method of using thermo-chemical vapor deposition apparatus. Alternatively, a method of forming a catalyst layer on a predetermined layer and allowing a carbon nanotube to be grown thereon may be employed.

Although a variety of methods of forming such carbon nanotubes may be considered, some embodiments of the invention proposes a method of forming the carbon nanotube layer 120 by attaching nanotubes (synthesized by a pulsed laser evaporation) on a predetermined layer in the form of a layer using a membrane method.

In detail, synthesized single barrier carbon nanotubes may be processed using chemical charge transfer doping so that the synthesized single barrier carbon nanotubes may have appropriate p-type carbon nanotube characteristics. For example, the carbon nanotubes are allowed to have p-type conductivity by exposing the carbon nanotubes to appropriate chemicals and generating spontaneous charge transfer between the dopant species and the nanotubes.

After that, the p-type carbon nanotubes are dispersed in an aqueous solution containing a surfactant and then a dispersed solution where the p-type carbon nanotubes are dispersed is filtered using a membrane to transfer the p-type carbon nanotubes onto the p-type GaN layer 110. Accordingly, the carbon nanotubes are attached on the p-type GaN layer 1 10, so that the p-type carbon nanotube layer 120 is formed on the p-type GaN layer 110.

Besides the membrane method, a method of allowing the carbon nanotubes to be directly grown on the p-type GaN layer 110 using a chemical vapor deposition (CVD) may be used.

Referring to FIG. 3, a metal contact 130 is formed on the p-type carbon nanotube layer 120. Such a metal contact 130 may be formed in a pattern using a lift-off method of forming a metal layer after a mask is formed and removing the mask to perform patterning, or a method of selectively etching and patterning that uses a mask after a metal layer is formed. For example, the metal layer may be formed using an epitaxial-beam (E-beam) deposition.

The metal contact 130 may be formed of a metal such as Ti, Al, Pt, Pd, and Au. Alternatively, the metal contact 130 may be a multi-layered metal contact in which layers of these metals are combined and stacked. For example, the metal contact 130 may consist of a Ti/Pt/Au multi-layer. Also, the metal contact 130 may be a Ti/Al/Pt/Au multi-layer or a Pd layer. After that, annealing may be performed at the temperature of about 700° C. under a nitrogen gas atmosphere.

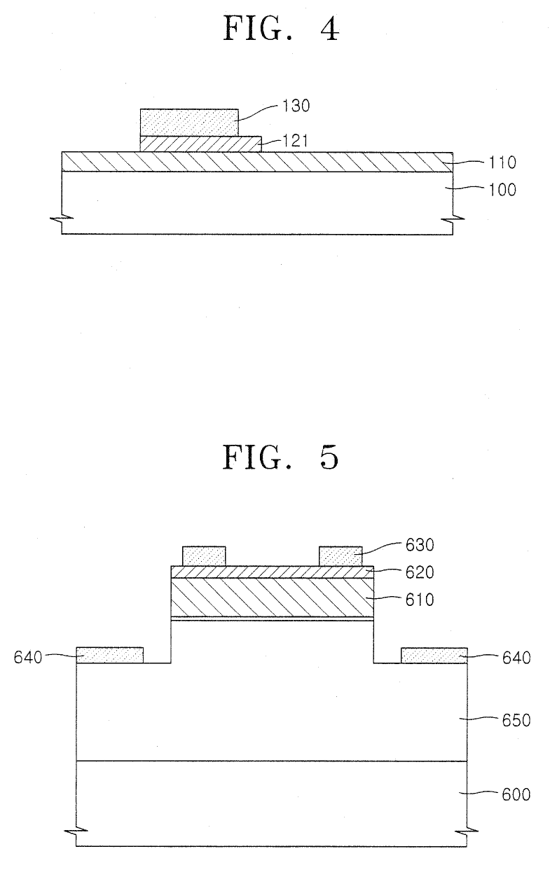

Referring to FIG. 4, after the metal contact 130 is formed, the p-type carbon nanotube layer 120 is patterned using selective etching, so that a pattern 121 of the carbon nanotube layer may be formed. For example, a portion of the p-type carbon nanotube layer exposed by a mesa structure of the metal contact 130 is etched during an etching process that uses an etching gas including a chlorine gas and an argon gas, so that the carbon nanotube layer pattern 121 may be formed. The carbon nanotube layer pattern 121 may be formed before the metal contact 130 is formed.

The resistance characteristics of the structure that includes the p-type GaN layer 110, the p-type carbon nanotube layer pattern 121, and the metal contact 130 may have the characteristics of a p-type ohmic contact. Accordingly, the structure of the p-type GaN layer 110, the p-type carbon nanotube layer pattern 121, and the metal contact 130 may be effectively used in improving a resistance problem when forming a p-junction using a p-type GaN layer 110 in realizing a semiconductor device having a p-n junction, a p-n-p junction, or n-p-n junction.

A resistance improvement resulting from the structure of the p-type GaN layer 110, the p-type carbon nanotube layer pattern 121, and the metal contact 130 according to some embodiments of the invention can be verified by considering the current (I) versus voltage (V) characteristics of a p-n junction structure. For that purpose, after the p-type carbon nanotube layer pattern 121 and the metal contact 130 are formed in a p-n junction structure including the p-type GaN layer 110, a current flowing through the p-n junction is measured.

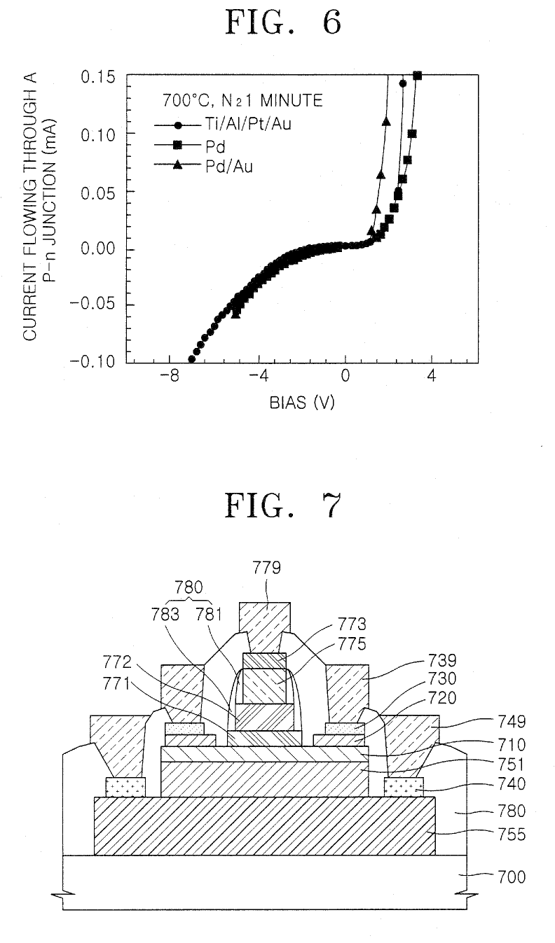

FIG. 5 is a schematic diagram illustrating an exemplary test piece that may be used in measuring I versus V characteristics of a p-n junction formed in accordance with embodiments of the invention. FIG. 6 is a graph illustrating the measured I versus V characteristics of the p-n junction formed in accordance with embodiments of the invention, which is helpful in explaining the resistance improvement effect of a p-type ohmic contact to a p-type semiconductor layer of a wide band gap compound that is achieved by embodiments of the invention.

Referring to FIGS. 5 and 6, the I versus V characteristics in the p-n junction structure illustrated in FIG. 5 have been measured to explain a resistance improvement effect of a p-type ohmic contact to a p-type semiconductor layer of a wide band gap compound.

Referring to FIG. 5, after an n⁺ GaN layer 650 is formed on a sapphire substrate 600, a mesa-shaped p⁺ GaN layer 610 and a mesa-shaped p⁺ carbon nanotube layer 620 are formed. The case where a quantum well structure is formed between the n⁺ GaN layer 650 and the mesa-shaped p⁺ GaN layer 610 has been considered. Therefore, an n-p junction structure is realized. At this point, the first metal contact 630 is formed on the p⁺ carbon nanotube layer 620, and the second metal contact 640 contacting the n⁺ GaN layer 650 is formed.

The second metal contact 640 may be understood as an n-type contact. Nevertheless, the first and second metal contacts 630 and 640 may be understood as contacts including substantially the same metal. Test pieces are formed in a structure in which the first and/or second metal contacts 630 and 640 include a Ti/Al/Pt/Au layer, a Pd layer, or a Pd/Au layer. After the metal contacts 630 and 640 are formed, annealing is performed at temperature of about 700° C. under nitrogen gas atmosphere for about one minute.

As illustrated in FIG. 6, a current flowing through a p-n junction is measured by applying a bias voltage to test pieces such as those illustrated as in FIG. 5. When considering the I-V characteristics illustrated in FIG. 6, it is possible to realize lower contact resistance by introducing a p-type carbon nanotube layer 620 to an interface between the p-type GaN layer 610 and the first metal contact 630, so that a p-type ohmic contact characteristics may be realized.

The contact resistance characteristics may be particularly effected depending on whether the annealing process is introduced or not. For example, when the annealing process is not performed, the carbon nanotube layer is measured to have specific resistance of about 5.4×10⁻³ Ω-cm². Alternatively, when the annealing process is performed at temperature of about 700° C. Under nitrogen gas atmosphere for about one minute, the carbon nanotube layer is measured to have specific resistance of about 1.31×10⁻⁴ Ω-cm², that is, the specific resistance is reduced by at least one power. In other words, the specific resistance is reduced by 1/10.

Also, when the annealing process is not performed, the interface between the carbon nanotube layer and the p-type GaN layer is measured to have specific resistance 0.12 Ω-cm². Alternatively, when the annealing process is performed, the specific resistance is reduced to 0.011 Ω-cm². Therefore, not only is the specific resistance of the carbon nanotube layer low but a reduction of the contact resistance of the interface between the carbon nanotube layer and the p-type GaN layer may be achieved.

The structure including the p-type carbon nanotube layer 620 and the first metal contact 630 on the p-type GaN layer 610 according to embodiments of the invention may realize a p-type ohmic contact to improve contact resistance, so that it is possible to use the p-type GaN layer 610 in realizing semiconductor devices such as an HBT, an HEMT, an LED, and a JBT. In particular, embodiments make it possible to introduce the p-type GaN layer for a base of an n-p-n HBT, which is a high power device. Therefore, the performance improvement of the HBT may be achieved.

FIG. 7 is a sectional diagram illustrating a HBT semiconductor device having a p-type ohmic contact to a p-type semiconductor layer of a wide band gap compound according to some embodiments of the invention.

Referring to FIG. 7, a transistor device according to the illustrated embodiments may include an HBT. For example, a base region 710 includes a mesa-shaped p-GaN layer on a substrate 700, mesa-shaped emitter regions 771 and 772 formed on the base region 710, and collector regions 751 and 755 formed below the base region 710, so that a HBT structure is formed.

In detail, as a bottom collector region layer, a layer (including an n⁺ GaN layer) for the second collector region 755 may be formed on a sapphire substrate 700 using an MOCVD or epitaxial growth. A layer (including an n⁻ GaN layer) for the first collector region 751, which is a substantial collector, may be formed on the layer for the second collector region 755.

After that, a layer (including a p⁻ GaN layer) for a base region 710 may be formed on the layer for the first collector region 751. A layer for the first emitter region 771, which is a substantial emitter, may be formed using an AlₓGa_{y}N layer, which is a Ga—N based compound layer, on the layer for the base region 710. After that, a layer (including an n⁺ GaN layer) for the second emitter 772 may be formed on the first emitter region 771.

Next, to form the first emitter contact 775 as an electrode, a metal layer, e.g., a metal layer stacking structure of Ti/Al/Pt/Au is formed and patterned. Then, mesa-shaped emitter regions 771 and 772 are patterned through a selective etching using the first emitter contact 775 for a mask and using spacers 780 formed of an insulation material at sidewalls.

For example, the first spacers 781 are formed on the sidewall of the first emitter contact 775 and a portion of the layer for the second emitter region 772 exposed by the first spacers 781 is selectively etched, so that the second mesa-shaped emitter region 772 is formed. After that, the second spacers 783 are formed using an insulation material on the sidewalls of the second emitter region 772, and a portion of the layer for the first emitter region 771 sequentially exposed by the second spacers 783 and the first emitter contact 775 is selectively etched, so that the first mesa-shaped emitter region 771 is formed.

Next, a layer for the base region 610 and a layer for the first collector region 751 at the lower portion sequentially exposed are selectively etched using a selective etching that uses a separate mask such as a photolithography process, so that the base region 610 having an upper surface partially exposed to both sides and the first collector region 751 aligned to the base region 610 are patterned. Next, a portion of a layer for the second collector region 755 exposed to the first collector region 751 is selectively etched and patterned such that the upper surface of the second collector region 755 is partially exposed.

Next, as described with reference to FIG. 2, a p-type carbon nanotube layer (120 in FIG. 2) is formed on the exposed surface of the base region 610. Next, the first base contact 730 (including a metal layer) contacting the carbon nanotube layer 120 is formed and patterned as described with reference to FIG. 3. Next, a portion of the exposed carbon nanotube layer is selectively etched using the first base contact 730 for a mask, so that a carbon nanotube layer pattern 720 aligned to the first base contact 730 is formed.

At this point, the first base contact 730 may be formed in a stacked structure of Ti/Pt/Au layers. Also, the second emitter contact 773 contacting the upper surface of the first emitter contact 775 may be formed. The first collector contact 740 contacting the upper surface of the second exposed collector region 755 may be formed in a stacked structure of Ti/Al/Pt/Au layers.

Next, after an insulation layer 780 is formed, contact holes exposing the first base contact 730, the second emitter contact 773, and the second collector contact 740 are formed and then the contact holes are filled, so that the second base contact 739, the third emitter contact 779, and the second collector contact 749 electrically connecting with the contact holes at the lower portions, respectively, may be formed in a stacked structure of Ti/Pt/Au layer, for example.

A transistor device formed in this manner may be understood as an n-p-n HBT device. The p⁻ base region 710 of the HBT device is formed of a p⁻ GaN layer, and the introduction of the p⁺ carbon nanotube layer pattern 720 contacting the p⁻ GaN layer may achieve improvement of the contact resistance. That is, a substantial p-type ohmic contact may be realized by electrical characteristics having mixed semiconductor characteristics and metal characteristics of the p⁺ carbon nanotube layer pattern 720 introduced to the interface between the base region 710 of the p⁻ GaN layer and the first base contact 730 providing a current to the base region 710.

Therefore, the contact resistance of the p⁻ GaN layer may be improved and thus the amount of a current substantially flowing through the p⁻ GaN layer may be effectively increased and the characteristic improvement of the HBT device may be achieved.

Though the description has been made using an n-p-n HBT device for an example in an embodiment of the present invention, the contact structure proposed by the present invention may be used for a transistor device such as an HEMT device, a JBT device, an MESFET device, and an MOSFET device. Also, the contact structure may be also used for a diode device that uses a p-n junction such as an LED device for blue light or white light.

According to the present invention, it is possible to improve both the sheet resistance and the contact resistance of the p-type semiconductor layer of a GaN based compound by introducing the p-type carbon nanotube layer on the p-type semiconductor layer of the GaN based compound.

This contact structure may be used for the transistor device such as an HBT, so that the performance of the power device such as an HBT may be remarkably improved.

The invention may be practiced in many ways. What follows are exemplary, non-limiting descriptions of some embodiments of the invention.

According to some embodiments, a semiconductor device having a wide band gap compound includes a p-type semiconductor layer of a Ga—N based compound formed on a substrate, a p-type carbon nanotube layer joined to the p-type semiconductor layer of the Ga—N based compound, and a metal contact joined to the layer of the p-type carbon nanotubes.

According to some embodiments, the p-type semiconductor layer of the Ga—N based compound may include one selected from the group consisting of Ga_{y}N and AlₓGa_{y}N.

According to some embodiments, the p-type semiconductor layer of the Ga—N based compound may be a semiconductor layer doped with Mg for impurity and thus having p-type conductivity.

According to some embodiments, the metal contact may include a layer selected from the group consisting of a Ti layer, an Al layer, a Pt layer, an Au layer, and a Pd layer, or include a stacked structure in which these layers are combined.

According to some embodiments, the metal contact may be a stacked structure of a Ti layer, an Al layer, and a Pt layer, a stacked structure of a Pd layer and an Au layer, or a Pd layer.

According to some other embodiments of the invention, an HBT semiconductor device includes a base region including a p-type semiconductor layer of a Ga—N based compound formed in a mesa shape on a substrate, a collector region partially exposed below the base region and including an n-type semiconductor layer of a Ga—N based compound, an emitter region formed on the base region in a mesa shape and including an n-type semiconductor layer of a Ga—N based compound such that a portion of the base region is exposed, a base metal contact applying a current to the base region, and a p-type carbon nanotube layer introduced such that one end of the p-type carbon nanotube layer is joined to an interface between the metal contact and the base region, and the other end of the layer of the p-type carbon nanotubes is joined to the metal contact.

According to some embodiment, the collector region may include an n⁻ GaN layer aligned in the base region and an n⁺ GaN layer having an upper surface exposed to both sides below the n⁻ GaN layer.

According to some embodiments, the emitter region may include an AlₓGa_{y}N layer formed on the base region and an n⁺ GaN layer formed on the AlₓGa_{y}N layer.

According to some embodiments, a collector metal electrode joined to the n⁺ GaN layer of the collector region and an emitter metal electrode joined to the n⁺ GaN layer of the emitter region may be further included.

According to some other embodiments of the invention, a method of manufacturing a semiconductor device having a wide band gap compound includes forming a p-type semiconductor layer of a Ga—N based compound on a substrate, joining a p-type carbon nanotube layer and the p-type semiconductor layer of the Ga—N based compound, and forming a metal contact to be joined to the layer of the p-type carbon nanotubes. p According to some other embodiments of the invention, a method of manufacturing a bipolar transistor semiconductor device includes forming a base region including a p-type semiconductor layer of a Ga—N based compound on a substrate, forming a collector region exposing a collector region located below the base region and including an n-type semiconductor layer of a Ga—N based compound, forming an emitter region including a mesa-shaped n-type semiconductor layer of a Ga—N based compound on the base region, forming a base metal contact applying a current to the base region, and forming a p-type carbon nanotube layer introduced such that one end of the layer of the p-type carbon nanotubes is joined to an interface between the metal contact and the base region, and the other end of the layer of the p-type carbon nanotubes is joined to the metal contact.

According to some embodiments the method may include, after the forming of the metal contact, performing an annealing so as to lower contact resistance between the metal contact and the p-type semiconductor layer of the Ga—N based compound.

According to embodiments of the invention, the contact resistance and/or sheet resistance between the p-type conductive layer of the semiconductor layer of the Ga—N based wide band gap and the contact may be reduced, so that it is possible to provide a semiconductor device such as BJT and HBT having improved performance by using the p-type conductive layer of the semiconductor layer of the Ga—N based wide band gap for a base.

While the invention has been particularly shown and described with reference to exemplary embodiments thereof, it will be understood by those of ordinary skill in the art that various changes in form and details may be made therein without departing from the spirit and scope of the present invention as defined by the following claims.

1. A semiconductor device comprising:
a p-type semiconductor layer disposed on a substrate, the p-type semiconductor layer comprising a Ga—N based compound;
a p-type carbon nanotube layer disposed on and in physical contact with the p-type semiconductor layer; and
a metal contact disposed on and in physical contact with the p-type carbon nanotube layer.

2. The semiconductor device of claim 1, the Ga—N based compound comprising at least one selected from the group consisting of GaN, AlₓGa_{y}N, and InₓGa_{y}N.

3. The semiconductor device of claim 1, the p-type semiconductor layer doped with magnesium (Mg) impurity ions.

4. The semiconductor device of claim 1, the metal contact comprising a first layer selected from the group consisting of a Ti layer, an Al layer, a Pt layer, an Au layer, and a Pd layer.

5. The semiconductor device of claim 4, the metal contact comprising a second layer stacked on a top surface of the first layer, the second layer selected from the group consisting of a Ti layer, an Al layer, a Pt layer, an Au layer, and a Pd layer.

6. The semiconductor device of claim 5, the metal contact comprising a third layer disposed in physical contact with a top surface of the second layer, the third layer selected from the group consisting of a Pt layer and a Pd layer.

7. The semiconductor device of claim 6, the metal contact comprising a fourth layer contiguous with a top surface of the third layer, the fourth layer consisting of an Au layer.

8. A method of manufacturing a semiconductor device, the method comprising:
forming a p-type semiconductor layer on a substrate, the p-type semiconductor device including a Ga—N based compound;
joining a p-type carbon nanotube layer to the p-type semiconductor layer; and
joining a metal contact to the the p-type carbon nanotube layer.

9. The method of claim 8, wherein forming the p-type semiconductor layer comprises forming one selected from the group consisting of GaN, AlₓGa_{y}N, and InₓGa_{y}N.

10. The method of claim 8, further comprising, after joining the metal contact to the p-type carbon nanotube layer, annealing to lower a contact resistance between the metal contact and the p-type semiconductor layer.

11. A bipolar transistor semiconductor device comprising:
a base region disposed on a substrate, the base region including a p-type semiconductor layer having a Ga—N based compound, the base region having a mesa shape;
a collector region disposed below the base region, the collector region including an n-type semiconductor layer having the Ga—N based compound, the collector region wider than the base region;
an emitter region disposed on the base region, the emitter region including an n-type semiconductor layer having the Ga—N based compound, the emitter region having a mesa shape, the emitter region contiguous with a top surface of the base region;
a metal contact configured to apply a current to the base region; and
a p-type carbon nanotube layer disposed between the metal contact and the base region, the p-type carbon nanotube layer abutting both the metal contact and the base region.

12. The bipolar transistor semiconductor device of claim 11, the Ga—N based compound comprising one selected from the group consisting of GaN, AlₓGa_{y}N, and InₓGa_{y}N.

13. The bipolar transistor semiconductor device of claim 11, the p-type semiconductor layer comprising magnesium (Mg) impurity ions.

14. The bipolar transistor semiconductor device of claim 11, further comprising:
a collector metal electrode joined to the collector region, the collector region including an n⁻ GaN layer aligned in the base region and an n⁺ GaN layer having an upper surface exposed to both sides below the n⁻ GaN layer, the n⁺ GaN layer joined to the collector metal electrode; and
an emitter metal electrode joined to the emitter region, the emitter region including an AlₓGa_{y}N layer formed on the base region and an n⁺ GaN layer formed on the AlₓGa_{y}N layer, the n⁻ GaN layer joined to the emitter metal electrode.

15. The semiconductor device of claim 11, the metal contact comprising a first layer selected from the group consisting of a Ti layer, an Al layer, a Pt layer, an Au layer, and a Pd layer.

16. The semiconductor device of claim 15, the metal contact further comprising a second layer contiguous with a top surface of the first layer, the second layer selected from the group consisting of a Ti layer, an Al layer, a Pt layer, an Au layer, and a Pd layer.

17. A method of manufacturing a bipolar transistor semiconductor device, the method comprising:
forming a base region on a substrate, the base region including a p-type semiconductor layer having a Ga—N based compound;
forming a collector region below the base region, the collector region wider than the base region, the collector region including an n-type semiconductor layer having the Ga—N based compound;
forming an emitter region on the base region, the emitter region having a mesa shape, the emitter region including a n-type semiconductor layer having the Ga—N based compound;
forming a metal contact configured to apply a current to the base region; and
forming a p-type carbon nanotube layer between the metal contact and the base region, the p-type carbon nanotube layer contiguous with the metal contact and the base region.

18. The method of claim 17, the Ga—N based compound comprising one selected from the group consisting of GaN, AlₓGa_{y}N, and InₓGa_{y}N.
